(19) United States
(12) Patent Application Publication
(10) Pub. No.: US 2009/0249164 A1
(43) Pub. Date: Oct. 1, 2009

(54) METHOD FOR SERIAL ASYNCHRONOUS TRANSMISSION OF DATA IN AN ARRAGEMENT FOR THE MONITORING, CONTROLLING, AND REGULATING AN OPERATIONAL CONTROL FACILITY OF BUILDING

(76) Inventor: Jorg Hammer, Hunenberg (CH)

Correspondence Address: STAAS & HALSEY LLP, SUITE 700, 1201 NEW YORK AVENUE, N.W., WASHINGTON, DC, 20005, US

(21) Appl. No.: 12/309,871

(22) PCT Filed: Aug. 2, 2007
(86) PCT No.: PCT/EP2007/058041

§ 371 Date: Feb. 2, 2009

(30) Foreign Application Priority Data
Aug. 2, 2006 (EP) 06118346.3

(51) Int. Cl. H03M 13/11; G06F 11/10; G06F 11/00

(52) U.S. Cl. 714/758; 714/E11.001

(57) ABSTRACT

In a method for the serial, asynchronous and character-by-character data transmission of a data stream having multiple data words Z to Z, an additional parity data word D is generated and transmitted. The parity data word D is generated such that in a data block formed from the data words Z to Z and the additional parity word D a pre-determined parity is produced, wherein for calculating the parity different bit positions, and thus varying priorities are selected each in the data words adjacent to each other in the data stream. Further, the vertical parity is generated and transmitted for the parity data word, and for each data word Z to Z. The method substantially increases the probability that transmission errors of various origins are detected in a receiver.

### CROSS REFERENCE TO RELATED APPLICATIONS

This application is based on and hereby claims priority to European Application No. EP06118346 filed on Aug. 2, 2006, the contents of which are hereby incorporated by reference.

### BACKGROUND

There are methods for secure transmission of data between a transmitter and a receiver via a common transmission medium, for example the transmitter being an input/output module for field apparatuses and the receiver an interface module by which said transmission medium is connected to a further communications system.

Methods of this type can be employed advantageously particularly in systems for monitoring, controlling, and/or regulating process variables in complex technical systems—heating, ventilation, and air conditioning systems; access and fire monitoring systems; and building automation systems in general (which are also referred to as building management systems) being named by way of example—in which indoor climatic variables are also particularly influenced. A large number of so-called field apparatuses such as sensors and control elements have to be operated as a rule in a building automation system. Bus systems are primarily used for the data exchange between individual system elements of the building automation system, a plurality of different types of bus systems invariably being employed in a system, which bus systems are connected to each other hierarchically as a rule.

A system for monitoring, controlling, and regulating an operational system of a building is known from EP 1 211 582 A1 for example. The system has a plurality of input/output modules for operating field apparatuses and a bus system by which the input/output modules are connected to each other. The bus system proposed to this effect is based, for example, on serial asynchronous data communications via a two-wire data bus.

A device for connecting a synchronous 16-bit data bus to a synchronous 64-bit data bus is known from EP 1 345 122 A1. In this respect, the clock frequency of the 16-bit data bus is roughly four times higher than the clock frequency of the 64-bit data bus. Within the device, a so-called DIP-4 (diagonal interleaved parity) coding method is utilized for error detection.

In the case of serial asynchronous data communications, a so-called NRZ (non return to zero) coding is employed as a rule. In this respect, the transmission of a character is initiated with the aid of a start bit. At the end of the character to be transmitted, a stop bit is appended. Additionally, a so-called parity bit can be inserted before the stop bit, by which an even or uneven parity is produced for the transmitted character. As a rule, the receiver synchronizes on the negative edge of the start bit and samples the following bits with its receiver clock rate. The defined parity allows certain transmission errors to be detected by the receiver.

If a message, which is formed from a plurality of characters, is then transmitted, an additional security field is often transferred in order to be able to check the accuracy of the overall message. Various methods are known for calculating the security field such as the formation of the arithmetic sum, the cyclic redundancy check (CRC) or the generation of vertical or horizontal parity, for example.

In the case of a serial asynchronous transmission of this type, errors can then arise if the time of sampling at the receiver is shifted so far that a stable signal condition is no longer detected. In the case of sampling shifted in time, the transition between two adjacent bits, or in an extreme case even the adjacent bit, is sampled incorrectly. The origin of such aberrant behavior lies, for example, in divergences between the clock frequencies at the transmitter and the receiver, in inaccuracy in the start bit synchronization or even in signal distortions. Divergences between the clock frequencies can be caused, for example, by component tolerances or by temperature differences between the transmitter and the receiver.

A certain difference between the clock frequencies of the transmitter and the receiver connected to same therefore results as a rule in the situation that the farther away the sampling point is from the start bit synchronization, the greater becomes the probability of an errored sampling. In the event that the last two bits transmitted are read incorrectly, this is not detected by the vertical parity. If this then happens in the case of an even plurality of characters, this cannot be detected by using horizontal parity either.

Particularly in a system with enhanced security requirements, such as in a building automation system in which high levels of damage or risk can arise for occupants through errored information transmission, security-related data streams have to be transmitted with corresponding reliability.

### SUMMARY

One possible object underlying the invention is to specify a method for serial asynchronous transmission of data by which an errored sampling can be detected with a high degree of probability and which can be applied and cost-effectively implemented particularly in a system for monitoring, controlling, and regulating an operational system of a building. Furthermore, a system can be specified with the aid of which the method can be carried out.

### BRIEF DESCRIPTION OF THE DRAWINGS

These and other objects and advantages of the present invention will become more apparent and more readily appreciated from the following description of the preferred embodiments, taken in conjunction with the accompanying drawings of which:

FIG. 1 shows a data connection in an arrangement for monitoring, controlling, and regulating an operational system of a building,

FIG. 2 shows information units secured for transmission via the data connection,

FIG. 2a shows a simplified representation of FIG. 2 with the data securing process for two bits of the information units in each case,

FIG. 3 shows a variant of a method for securing information units,

FIG. 4 shows a further representation of information units secured,

FIG. 5 shows a system for carrying out the method,

FIG. 6 shows a representation with reference to an advantageous implementation of the method, and

FIG. 7 shows a further variant of a method for securing information units.

### DETAILED DESCRIPTION OF THE PREFERRED EMBODIMENT

Reference will now be made in detail to the preferred embodiments of the present invention, examples of which are illustrated in the accompanying drawings, wherein like reference numerals refer to like elements throughout.

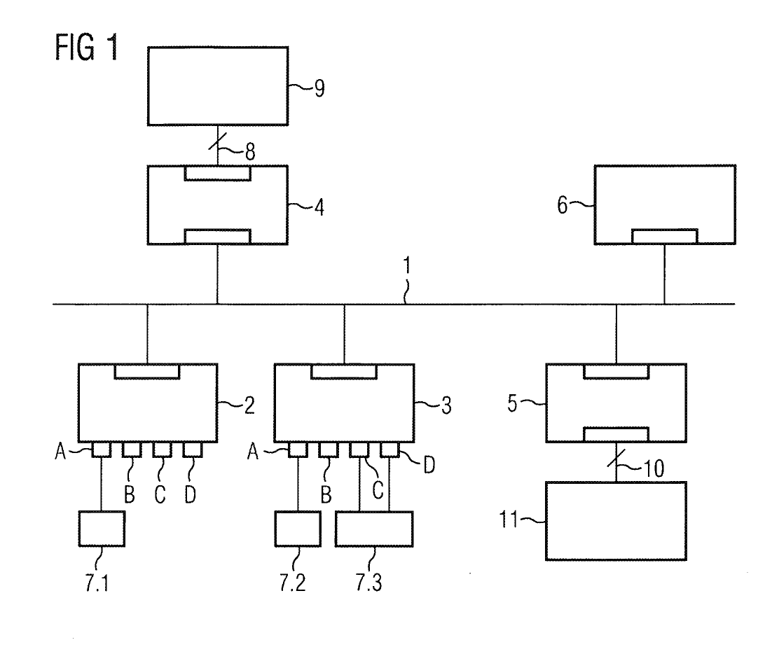

In FIG. 1, 1 signifies a transmission medium for connecting units 2, 3, 4, 5, and 6 of a system for monitoring, controlling, and/or regulating an operational system of a building.

By way of example, a first unit 2 and a second unit 3 each comprise an input/output module for operating field apparatuses 7. A field apparatus 7 typically comprises a sensor for capturing a process variable or an actuator for influencing a process variable.

Naturally, the plurality of input/output modules 2 and 3 connected to each other via the transmission medium 1 is not restricted to just two as represented in FIG. 1.

Advantageously, the input/output module 2 or 3 respectively has a plurality of contact points A, B, C, and D for field apparatuses 7. The plurality of contact points implemented per input/output module 2 or 3 is selectable within broad limits and tailored to reflect permissible module costs, space requirements, and the anticipated data stream per unit of time. Eight or sixteen contact points per input/output module 2 or 3 are realized, for example, with regard to building automation systems.

Advantageously, the contact points A, B, C, and D are constructed identically and, for example, can be employed universally as input ports and as output ports, that is to say bidirectionally and in fact for analog signals and digital signals. The contact points A, B, C and D each have, for example, three terminal connecting points for the field apparatus 7. The universal contact point A, B, C or D can therefore be utilized for a large number of field apparatus types and in fact for sensors or actuators, that is to say for field apparatuses with analog input, analog output, digital input or digital output, with or without supply via the contact point A, B, C or D in each case.

Typical field apparatuses 7 in building automation systems comprise, for example, temperature probes, moisture probes, gas sensors, door contacts, smoke sensors, valve and air flap drives, sprinkler valves, light switches, and drives for Venetian blinds.

Depending on the type of field apparatus, therefore, the field apparatus 7 is connected to the contact point A, B, C or D by a two-core or multi-core method. Where necessary, the field apparatus 7 is connected to a plurality of contact points, specifically, for example, when the field apparatus 7 comprises a control element with position feedback, the actuating signal then being output advantageously at a first contact point A and a condition or the current position of the control element being read in simultaneously at a second contact point B.

For example, a contact point A of the input/output module 2 is connected to a temperature probe 7.1, while a gas sensor 7.2 is connected to a contact point A and a control element 7.3 is connected to contact points C and D of the input/output module 3.

Advantageously, a third unit 4 connected to the transmission medium 1 comprises a regulating and/or control apparatus or an interface module connected via a further communications system 8 to a higher-level regulating and/or control apparatus 9, by which the transmission medium 1 and the further communications system 8 are physically and logically adapted to each other for a data exchange, different types of signal carrier and different types of data transmission protocols being tailored to each other by the interface module as a rule.

In a variant of the system, the third unit 4 is connected via the further communications system 8 to a higher-level center or control point.

A fourth unit 5 comprises, if necessary, a further interface module, which is connected via an additional communications system 10 to a further apparatus 11. The communications systems 8 and 10 are provided in principle by the communications capabilities of the regulating and/or control apparatus 9 or the further apparatus 11 respectively and implemented, for example, by bus systems and technologies such as LON or LonWorks®, the European Installation Bus EIB, the PROFIBUS defined in accordance with the German standard DIN 19245, BACnet or KONNEX. In principle, the communications system 8 or 10 can also be realized by optical data communications channels or a radio communications network, for example by a fiber optic network or a cellular telephone network, such as e.g. GSM or UMTS.

A fifth unit 6 comprises a service module, which can be connected to the transmission medium 1 if necessary. The service module 6 is used, for example, for the configuration of sub-functions of the building automation system, the commissioning or monitoring of units 2 and 3 connected to the transmission medium 1, or the localization of malfunctions.

In principle, the data communications via the transmission medium 1 are effected along wires or wirelessly. In the case of communications along wires, the transmission medium 1, to which the five units 2, 3, 4, 5, and 6 are connected, comprises, by way of example, a two-wire bus or a two-core wire.

In a variant, a unit for supplying the units 2, 3, 4, 5, and 6, and/or a unit for supplying the connected field apparatuses 7 are also available, the electrical supply, if necessary with additional electrical wires, being distributed together with the transmission medium 1 advantageously in a common bus system.

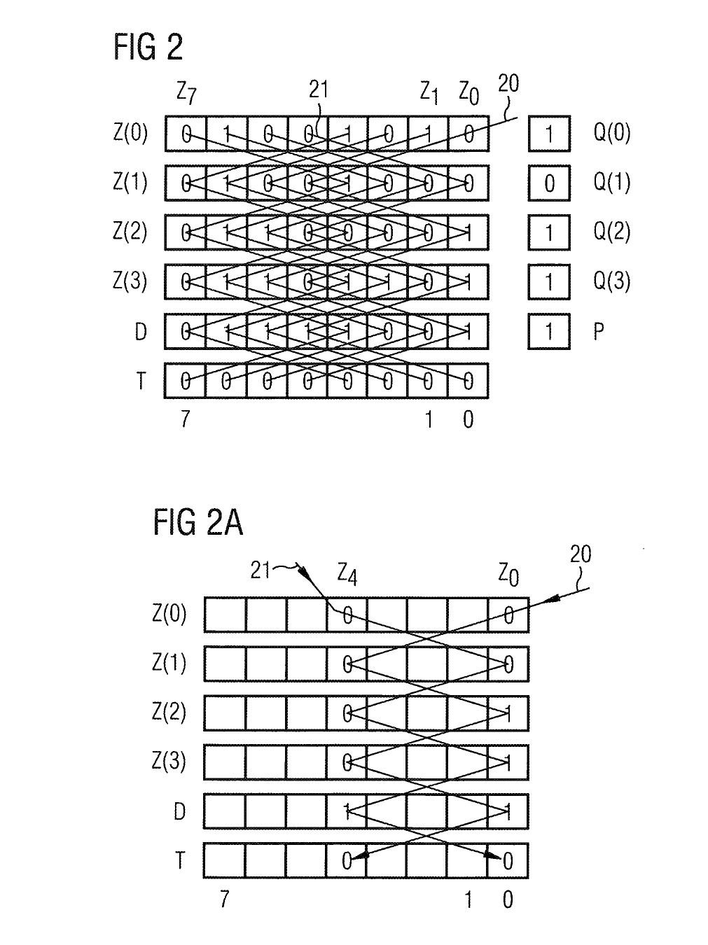

In a first example, a data stream to be transmitted via the transmission medium 1 has four information units Z(0), Z(1), Z(2), and Z(3) (FIG. 2). In this case, the information units Z(0), Z(1), Z(2), and Z(3) have a word length of 8 bits each. In this case, the individual bits of an information unit are designated from the lowest significance Z0 through to the highest significance Z7.

Prior to transmission, the information units Z(0), Z(1), Z(2), and Z(3) are secured by the following two steps:

Step 1: Generation of a corresponding vertical parity bit Q(0), Q(1), Q(2) or Q(3) for each information unit Z(0), Z(1), Z(2), and Z(3). In this case, an even parity is produced, by way of example, with reference to the associated information unit by the vertical parity bit, that is to say the plurality of bits set to logical one in the information unit and in the assigned vertical parity bit is even.

Step 2: Generation of an additional parity data word D from the four information units Z(0), Z(1), Z(2), and Z(3) in such a way that a predetermined parity is produced in a data block formed from the four information units each having a word length of eight and the additional parity data word D, different bit positions and therefore differing significances being selected in the case of adjacent information units or data words in the data stream in each case for the purposes of calculating the parity. In this case, by way of example, the additional parity data word D has the same word length as the information units Z(0), Z(1), Z(2), and Z(3), specifically eight.

FIG. 2 represents an advantageous variant of Step 2, in which bits spaced four bit positions apart are used in each case in the case of adjacent data words in the data stream for the purposes of calculating the parity. The advantageous distance between the bit positions under consideration arises from half the word length of the information units Z(0), Z(1), Z(2), and Z(3). To give a clearer representation, two linking paths 20 and 21 of the total of eight linking paths represented in FIG. 2 are marked in once again separately in FIG. 2a. A zigzag-shaped linking path 20 illustrates the calculation for the least significant bit of the parity data word D. The least significant or first bit Z0 of the first information unit Z(0), the fourth most significant or fifth bit Z4 of the second information unit Z(1), the least significant bit Z0 of the third information unit Z(2), and the fifth bit Z4 of the fourth information unit Z(3) determine the least significant bit of the parity data word D. In the example shown, an even parity is produced with the parity data word D, that is to say therefore that the plurality of logical values “1” of the bits under consideration—including the corresponding bit of the parity data word D—is even. It is self evident that an uneven parity could be generated in an alternative variant of the data securing process for the data block.

A further zigzag-shaped linking path 21 illustrates the calculation for the fourth most significant or fifth bit of the parity data word D. The fifth bit Z4 of the first information unit Z(0), the least significant bit Z0 of the second information unit Z(1), the fifth bit Z4 of the third information unit Z(2) and the least significant bit Z0 of the fourth information unit Z(3) determine the fourth most significant or fifth bit of the parity data word D.

Additionally, a parity bit P is also generated with reference to the parity data word D, by which the same type of parity is produced, advantageously, as in the case of the information units Z(O), Z(1), Z(2), and Z(3).

If the parity is produced via a data block formed from the information units Z(0), Z(1), Z(2), and Z(3) and the parity data word D in accordance with the formation rule represented in FIG. 2 and FIG. 2a, a binary zero is produced in each case at all bit positions for an additional data word T. An errored parity in the transmitted data block can be ascertained more simply in a receiver as a result of this fact.

It has become apparent that the embodiment of the data saving of the data block represented in FIG. 2, in which bits belonging to adjacent information units that are used for forming a parity bit are spaced half a word length of the information units Z(0), Z(1), Z(2), and Z(3) apart in each case, markedly increases error detection on the one hand and can be implemented with little effort by using a microprocessor on the other. As a rule, the command set of a microprocessor includes a command by which the two halves of a register or any desired addressed data word are interchanged, with the result that the identified variant can be programmed particularly simply and additionally enables program code with relatively short runtimes.

For the purposes of generating an advantageous parity data word D for a sequence with a plurality k of information units Z(i), the following basic formula G1 can be employed:

$${D}_{a} = ( {\sum }_{i = 0}^{k - 1} {Z ( i )}_{( i + a + k ) mod n} ) mod 2 ∀ a ∈ \{ 0 … m - 1 \}$$

In this basic formula G1,

m stands for the word length of the parity data word D

n stands for the word length of the information units Z(i)

k stands for the plurality of information units

Dₐ stands for the calculated bit at the position a in the parity data word D

i stands for the position of the information unit in the sequence starting with Z(0) up to Z(k−1)

Z(i)ⱼ stands for the bit at the position j in an information unit Z(i)

mod stands for the mathematical modulo function, that is to say the remainder of the whole-number division

Depending on the required spacing between the bits of two adjacent information units taken into account for the purposes of generating the parity and their direction of spacing—shifted positively versus negatively or to the left versus to the right—the basic formula G1 can be adapted to the requirements with little effort.

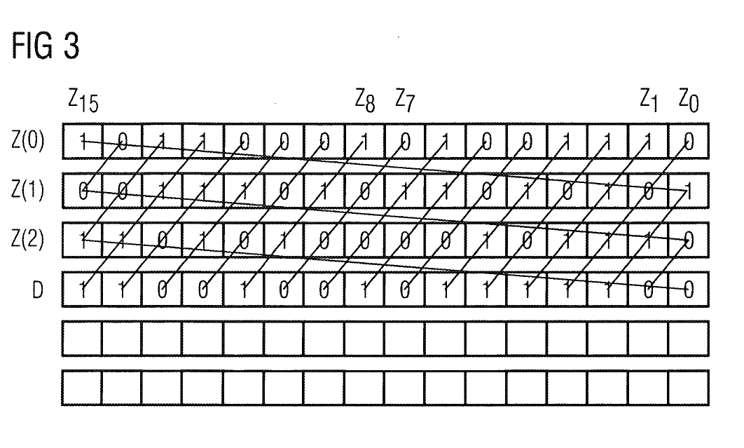

FIG. 3 shows a variant for forming a parity data word D, information units Z(0), Z(1), and Z(2) having 15 bits in each case, as the parity data word D does also, in this example. For the purposes of calculating the parity in the case of adjacent information units in the data stream, bits spaced one bit position apart in each case are linked. This simple variant has the advantage that mainly one-bit shift or one-bit rotation commands taking up a few machine cycles can be employed, alongside word-by-word Exclusive-Or commands, for an implementation using a low-cost microprocessor, which overall enables particularly short program runtimes.

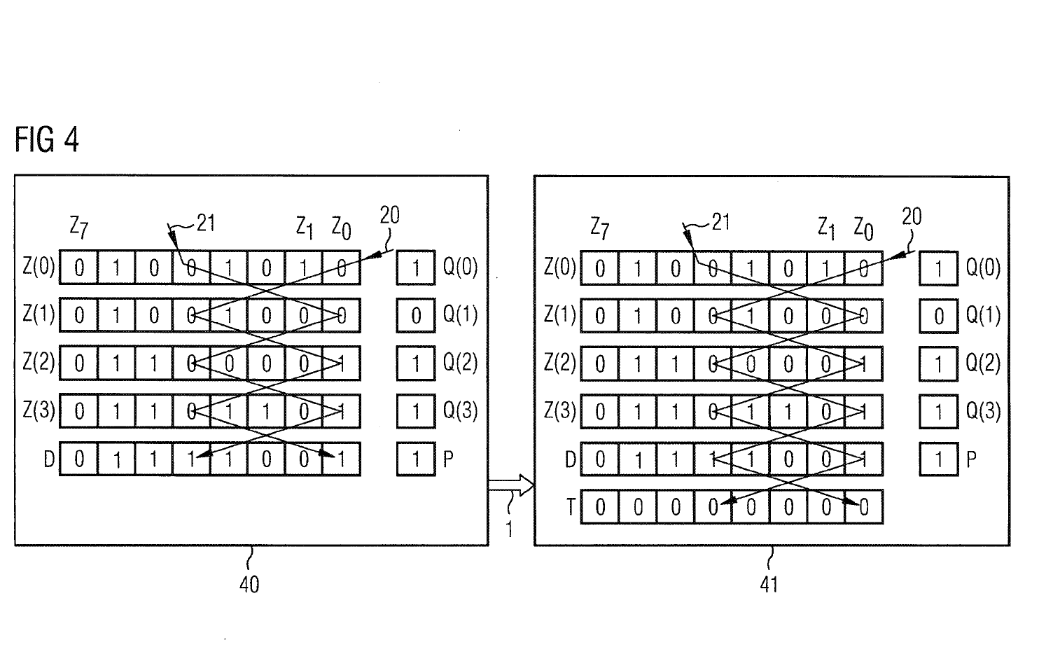

In FIG. 4, the information units Z(0), Z(1), Z(2), and Z(3) secured by means of the parity data word D and the vertical parity bits Q(0), Q(1), Q(2), Q(3), and P are processed in a transmit module 40. A data block containing the information units Z(0), Z(1), Z(2), and Z(3) and the parity data word D is transmitted character-by-character including the associated vertical parity bit via the transmission medium 1 to a receive module 41. In the receive module 41, the transmitted data block is analyzed. A transmission error is expressed with a high degree of probability by the fact that either at least one of the vertical parities ascertained in the receive module does not match the transferred parity bit Q(0), Q(1), Q(2), Q(3) or P, or the value of the additional data word T calculated in the receive module 41 does not match the anticipated value. Depending on whether even or uneven parity is produced with the parity data word D, all the bits in the additional data word are set to zero or then to one in the case of error-free transmission.

Each of the units 2, 3, 4, 5, and 6 connected to the transmission medium 1 has an instance of the transmit module 40 and an instance of the receive module 41 available to it, the transmit module 40 and the receive module 41 being implemented advantageously as a transceiver module in each case.

In FIG. 5, the two units 2 and 4 connected to the transmission medium 1 are represented in rather more detail.

The unit 2 and the unit 4 each have an interface facility 50, which advantageously has an input/output buffer memory 51 available to it. The interface facility 50 enables bidirectional data communications between the two units 2 and 4 via the transmission medium 1. An advantageous implementation of the unit 2 and also of the unit 4 additionally has at least one microprocessor 52, a program 53, and an additional memory area 54 for the data stream containing the information units Z(0), Z(1), Z(2), and Z(3) and the parity data word D. Advantageously, the program 53, which is tailored to the microprocessor 52, is designed in such a way that the two units 2 and 4 are capable of operating both as transmitter and also as receiver with regard to the data communications proceeding via the transmission medium 1.

In the unit 2 employed as a transmitter, for example, the microprocessor 52 is controlled by the program 53 in such a way that an additional parity data word D is generated from the four information units Z(0), Z(1), Z(2), and Z(3) in such a way that a predetermined parity is produced in a data block formed from the four information units Z(0), Z(1), Z(2), and Z(3), which each have a certain word length, and the additional parity data word D, different bit positions and therefore differing significances being selected in the case of adjacent information units or data words in the data stream to be transmitted in each case for the purposes of calculating the parity.

In the unit 4 utilized as a receiver, for example, the microprocessor 52 is controlled by the program 53 in such a way that the parity in the received data stream is produced via a data block formed from the information units Z(0), Z(1), Z(2), and Z(3) and the parity data word D and an additional data word T. The value of the additional data word T is used in the program 53 for the purposes of detecting transmission errors.

It is self-evident that a correspondingly designed electronic circuit could in principle also be employed in place of the microprocessor 52 and the program 53 if necessary.

As already mentioned in relation to FIG. 2 or FIG. 2a, the command set of a microprocessor includes as a rule a command by which the two halves of a register or any desired, addressable data word are interchanged. Said command for interchanging the two halves of a data word—also, designated as SWAP in certain command sets—therefore interchanges, for example, in an eight-bit data word, the least significant bit with the fourth most significant bit, the second bit with the third most significant bit, and so on.

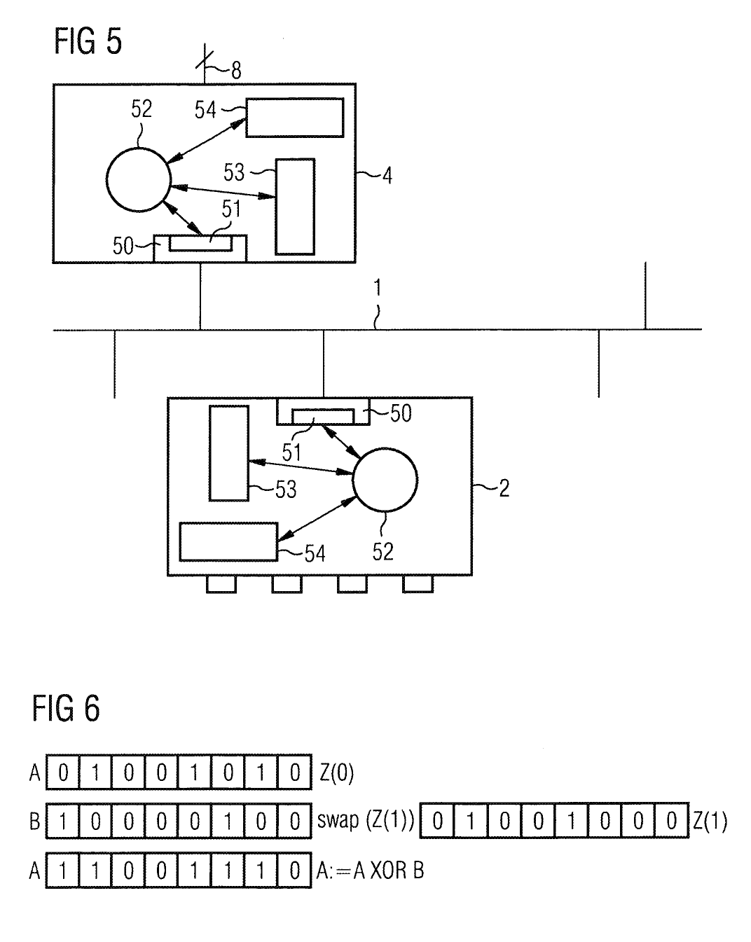

FIG. 6 shows the principle of an advantageous implementation of the generation, of the parity data word D. To this effect, an extract from the program 53 is sketched. The first information unit Z(0) is stored in a register A of the microprocessor 52, while the second information unit Z(1) is available in the memory area 54 for the microprocessor 52. In an operation of the microprocessor 52 symbolized by swap(Z(1)), the contents of the second information unit Z(1) are transferred to a register B of the microprocessor 52, the low half and the high half of the second information unit Z(1) being interchanged in this respect. Then, in an operation of the microprocessor 52 symbolized by A:=A XOR B, the contents of the two registers A and B are compared with each other in such a way that the result of a so-called Exclusive-Or operation on the two registers A and B is stored in register A. Subsequently, and not represented in FIG. 6, an Exclusive-Or operation is carried out on the contents of the register A and the third information unit and the result once again placed in register A. Finally, an Exclusive-Or operation is also carried out on the contents of the register A and the half interchanged third information unit Z(3) and the result placed in the register A, at which point the parity data word D is available in the register A. In the case of longer data streams, individual program steps of the program extract shown are repeated correspondingly, every second information unit therefore in principle having to be half interchanged prior to the Exclusive-Or operation.

In further advantageous variants, different bit positions and therefore differing significances are selected in the case of adjacent data words in the data stream in each case for the purposes of calculating the parity in such a way that, on the one hand, the significances of adjacent data words are spaced different amounts apart and a cycle between two operations, in which operations an identical pair formation results in the case of the selection of the bit positions taken into account for the operations, is as long as possible. A high level of security in variants of this type is achievable if the cycle between two operations, in which operations an identical pair formation results in the case of the selection of the bit positions taken into account for the operations, is equal to the plurality k of the information units Z(i) in the data stream.

Advantageously, the sequence of the significances or bit positions taken into account is captured in a first vector K^{{0 . . . n-1}} and a bit-position-dependent offset dependent on the bit position in the parity data word D in a second vector L^{{0 . . . m-1}} for variants of this type. For the purposes of calculating the parity for variants of this type, the basic formula G1 set out above is transformed by a first vector K^{{0 . . . n-1}} and a second vector L^{{0 . . . m-1}} into a more general formula G2:

$${D}_{a} = ( {\sum }_{i = 0}^{k - 1} {Z ( i )}_{K ( ( L ( a ) + i + k ) mod n )} ) mod 2 ∀ a ∈ \{ 0 … m - 1 \}$$

In this more general formula G2 also,

m stands for the word length of the parity data word D

n stands for the word length of the information units Z(i)

k stands for the plurality of information units

Dₐ stands for the calculated bit at the position a in the parity data word D

i stands for the position of the information unit in the sequence starting with Z(0) up to Z(k−1)

Z(i)ⱼ stands for the bit at the position j in an information unit Z(i)

mod stands for the mathematical modulo function, that is to say the remainder of the whole-number division

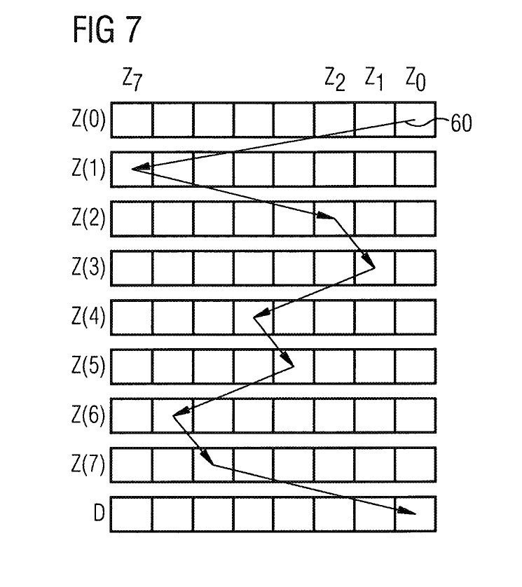

In FIG. 7, a continuous line 60 shows the sequence path of the operations carried out during the calculation of the least significant bit of the parity data word D. By way of example, the advantageous sequence path according to the more general formula G2 is determined by the first vector K=[0 7 2 1 4 3 6 5] and the second vector L=[0 3 2 5 4 7 6 1].

The invention has been described in detail with particular reference to preferred embodiments thereof and examples, but it will be understood that variations and modifications can be effected within the spirit and scope of the invention covered by the claims which may include the phrase “at least one of A, B and C” as an alternative expression that means one or more of A, B and C may be used, contrary to the holding in Superguide v. DIRECTV, 69 USPQ2d 1865 (Fed. Cir. 2004).

1-12. (canceled)

13. A method for serial, asynchronous data transmission of a data stream from a transmit module to a receive module, the data stream having a plurality of data words of a constant word length n and being transmitted character-by-character, comprising:
generating an additional parity data word D with a word length m from a predetermined plurality k of data words of the data stream, the additional parity word being generated in the transmit module in such a way that a predetermined parity is produced in a data block formed from the k data words of length n and the additional parity data word of length m, the parity of the data block being determined by selecting different bit positions and therefore differing significances for adjacent data words in the data stream;
generating an associated vertical parity bit for each of the k data words of the data block, each parity bit being determined with reference to the parity word; and
transmitting the data block of k data words and the parity data word D character-by-character, each of the k data words being transmitted with the associated vertical parity bit.

14. The method as claimed in claim 13, wherein
to calculate parity for adjacent data words, a lower half of a first adjacent data word is linked on a bit-by-bit basis with a higher half a second adjacent data word,
the first adjacent data word is a data word to be sent out earlier in time, and
the second adjacent data word is a data word to be sent out later in time.

15. The method as claimed in claim 13, wherein
to calculate parity for adjacent data words, a higher half of a first adjacent data word is linked on a bit-by-bit basis with a lower half a second adjacent data word,
the first adjacent data word is a data word to be sent out earlier in time, and
the second adjacent data word is a data word to be sent out later in time.

16. The method as claimed in claim 13, wherein the word length m of the parity data word is equal to the word length n of the data words in the data stream.

17. The method as claimed in claim 13, wherein,
given a running variable i from 0 to n−1 and a whole-number constant a from 1 to n−1, a value is calculated for a first bit at a position k(i mod n) in the parity data word and a value is calculated for a second bit at a position (k+1)((i+a) mod n) for the purposes of generating the parity data word.

18. The method as claimed in claim 13, wherein
the bit positions and therefore the significances of adjacent data words are spaced different amounts apart, and
a cycle between two operations, in which operations an identical pair formation results in the case of the selection of the bit positions taken into account for the operations, is equal to the quantity k of data words in the data stream.

19. A system for monitoring, controlling, and regulating an operational system of a building, comprising:
a transmit module;
a receive module; and
a data line connecting the transmit and the receive module wherein
the transmit module comprises:
a first generating unit to generate an additional parity data word with a word length m from a predetermined plurality k of data words in of the data stream in such a way that a predetermined parity is produced in a data block formed from the k data words of length n and the additional parity data word of length m, the parity of the data block being determined by selecting different bit positions and therefore differing significances for adjacent data words in the data stream;
a second generating unit to generate an associated vertical parity bit for each of the k data words of the data block, each parity bit being generated with reference to the parity word; and
a transmission unit to transmit the data block of k data words and the parity data word D character-by-character, each of the k data words being transmitted with the associated vertical parity bit.

20. The system as claimed in claim 19, wherein the receive module comprises:
a third generating unit to generate an additional parity data word with a word length m from a predetermined plurality k of data words in of the data stream in such a way that a predetermined parity is produced in a data block formed from the k data words of length n and the additional parity data word of length m, the parity of the data block being determined by selecting different bit positions and therefore differing significances for adjacent data words in the data stream.

21. The system as claimed in claim 19, wherein
a regulating or control apparatus contains the transmit module, and
an input/output module contains the receive module.

22. The system as claimed in claim 19, wherein
an input/output module contains the transmit module, and
a regulating or control apparatus contains the receive module.

23. The system as claimed in claim 19, wherein an interface module contains the transmit module.

24. The system as claimed in claim 19, wherein an interface module contains the receive module.

25. The system as claimed in claim 20, wherein
a regulating or control apparatus contains the transmit module, and
an input/output module contains the receive module.

26. The system as claimed in claim 20, wherein
an input/output module contains the transmit module, and
a regulating or control apparatus contains the receive module.

27. The system as claimed in claim 20, wherein an interface module contains the transmit module.

28. The system as claimed in claim 20, wherein an interface module contains the receive module.
